(19) United States
(12) Patent Application Publication
(10) Pub. No.: US 2024/0322758 A1
(43) Pub. Date: Sep. 26, 2024

(54) POWER AMPLIFIER CIRCUIT

(71) Applicant: Murata Manufacturing Co., Ltd., Nagaokakyo-shi (JP)

(72) Inventors: Yuuma NOGUCHI, Nagaokakyo-shi (JP); Kiichiro TAKENAKA, Nagaokakyo-shi (JP); Tomohide ARAMATA, Nagaokakyo-shi (JP); Takeshi KOGURE, Nagaokakyo-shi (JP); Takaya WADA, Nagaokakyo-shi (JP)

(21) Appl. No.: 18/668,341

(22) Filed: May 20, 2024

Related U.S. Application Data
(63) Continuation of application No. PCT/JP2022/039129, filed on Oct. 20, 2022.

(30) Foreign Application Priority Data
Nov. 30, 2021 (JP) 2021-193910

(51) Int. Cl. H03F 1/02; H03F 3/24

(52) U.S. Cl. CPC H03F 1/0233; H03F 3/245; H03F 2200/105; H03F 2200/451

(57) ABSTRACT

A power amplifier circuit includes a power amplifier configured to amplify radio-frequency signal, a supply voltage terminal coupled to the power amplifier, and a bypass capacitor coupled between ground and a supply voltage path connecting the supply voltage terminal to the power amplifier. A supply voltage (V_{DET}) is configured to be supplied to the power amplifier through the supply voltage terminal, and the supply voltage (V_{DET}) is configured to vary across multiple discrete voltage levels within a single frame of radio-frequency signals. The first bypass capacitor has an electrostatic capacity equal to or higher than a specific value that is determined to cause the power amplifier circuit with the first supply voltage to have a higher efficiency than a threshold efficiency. In some exemplary embodiments, the bypass capacitor has an electrostatic capacity equal to or higher than 1.4 nanofarads.

### CROSS REFERENCE TO RELATED APPLICATIONS

This application is a continuation of International Application No. PCT/JP2022/039129, filed Oct. 20, 2022, which claims priority to Japanese Patent Application No. 2021-193910, filed Nov. 30, 2021, the entire contents of each of which are hereby incorporated by reference in their entirety.

### TECHNICAL FIELD

The present disclosure relates to power amplifier circuits.

### BACKGROUND

In recent years, envelope tracking (ET) mode has been employed to improve power efficiency in power amplifier circuits. An example circuit, as described in U.S. Pat. No. 8,829,993, uses a technique for supplying multiple discrete voltages in ET mode (hereafter referred to as digital ET mode).

### SUMMARY OF THE INVENTION

However, when supply voltage is provided to power amplifier circuits in digital ET mode, the power amplifier circuit efficiency may degrade.

The present disclosure provides power amplifier circuits designed to improve the power amplifier circuit efficiency in digital ET mode.

A power amplifier circuit according to an exemplary aspect of the present disclosure includes a power amplifier configured to amplify a radio-frequency signal, a supply voltage terminal coupled to the power amplifier, and a first bypass capacitor coupled between ground and a supply voltage path connecting the supply voltage terminal to the power amplifier. A first supply voltage is configured to be supplied to the power amplifier through the supply voltage terminal, and the first supply voltage is configured to vary across a plurality of discrete voltage levels within a single frame of the radio-frequency signal. The first bypass capacitor has an electrostatic capacity equal to or higher than a specific value that is determined to cause the power amplifier circuit with the first supply voltage to have a higher efficiency than a threshold efficiency. In some exemplary embodiments, the threshold efficiency corresponds to an efficiency of the power amplifier circuit in an average power tracking mode. In some exemplary embodiments, the first bypass capacitor has an electrostatic capacity equal to or higher than 1.4 nanofarads.

A power amplifier circuit according to an aspect of the present disclosure includes a power amplifier configured to amplify a radio-frequency signal, a supply voltage terminal coupled to a digital envelope tracker, and a first bypass capacitor coupled between ground and a supply voltage path connecting the supply voltage terminal to the power amplifier. The first bypass capacitor has an electrostatic capacity equal to or higher than a specific value that is determined to cause the power amplifier circuit with the digital envelope tracker to have a higher efficiency than a threshold efficiency. 1.4 nanofarads.

The power amplifier circuits according to some aspects of the present disclosure improve the power amplifier circuit efficiency in digital ET mode.

### BRIEF DESCRIPTION OF DRAWINGS

FIG. 1 is a circuit configuration diagram of a communication device according to a first exemplary embodiment.

FIG. 2A is a graph illustrating an example of supply voltage variations in digital envelope tracking mode.

FIG. 2B is a graph illustrating an example of supply voltage variations in analog envelope tracking mode.

FIG. 2C is a graph illustrating an example of supply voltage variations in average power tracking mode.

FIG. 3 is a graph illustrating the relationship between the electrostatic capacity of a bypass capacitor and the efficiency of a power amplifier circuit in the first exemplary embodiment.

FIG. 4 is a circuit configuration diagram of a communication device according to a second exemplary embodiment.

FIG. 5 is a circuit configuration diagram of a power amplifier circuit according to a modification.

FIG. 6 is a plan view of a power amplifier module according to a practical example.

FIG. 7 is a plan view of the power amplifier module according to the practical example.

FIG. 8 is a sectional view of the power amplifier module according to the practical example.

### DETAILED DESCRIPTION OF EMBODIMENTS

Hereinafter, exemplary embodiments of the present disclosure will be described in detail with reference to the drawings. The exemplary embodiments described below represent comprehensive or specific examples. Details such as numerical values, shapes, materials, constituent elements, and arrangements and connection modes of the constituent elements provided in the following exemplary embodiments are illustrative and are not intended to limit the present disclosure.

The drawings are schematically illustrated with necessary emphasis, omissions, or proportion adjustments to depict the present disclosure and do not necessarily represent exact details; thus, the shapes, positional relationships, and proportions can differ from actual implementations. Identical reference numerals are assigned to substantially the same configuration elements across the drawings, and redundant descriptions of these configuration elements can be omitted or simplified.

In the drawings described below and for purposes of this disclosure, the x-axis and the y-axis are perpendicular to each other in a plane parallel to the major surfaces of a module substrate. According to an exemplary aspect, when the module substrate is rectangular in plan view, the x-axis is parallel to a first side of the module substrate, and the y-axis is parallel to a second side perpendicular to the first side of the module substrate. The z-axis is perpendicular to the major surfaces of the module substrate. Along the z-axis, the positive direction indicates upward, and the negative direction indicates downward.

In the circuit configurations of the present disclosure, the term “couple” applies when one circuit element is directly coupled to another circuit element via a connection terminal and/or an interconnect conductor. The term also applies when one circuit element is electrically coupled to another circuit element via still another circuit element. The expression “coupled between A and B” refers to a situation in which a circuit element is coupled to both A and B, positioned between A and B, in other words, the circuit element is coupled in series in the path connecting A and B.

In the component layouts of the present disclosure, the expression “a component is disposed at a substrate” applies when the component is disposed at a major surface of the substrate and also when the component is disposed inside the substrate. The expression “a component is disposed at a major surface of a substrate” applies when the component is disposed in contact with the major surface of the substrate and also when the component is disposed above the major surface without making contact with the major surface (for example, when the component is stacked on another component that is disposed in contact with the major surface). The expression “a component is disposed at a major surface of a substrate” may apply when the component is disposed in a depressed portion formed at the major surface. The expression “a component is disposed inside a substrate” applies when the component is encapsulated in the module substrate; additionally, the expression applies when the component is entirely positioned between the two major surfaces of the substrate but not fully covered by the substrate and also applies when only a portion of the component is disposed inside the substrate.

In the component layouts of the present disclosure, the term “plan view of a module substrate” refers to a situation in which an object is orthogonally projected onto an xy-plane and viewed from the positive side of the z-axis. The expression “A overlaps B in plan view” refers to a situation in which at least a portion of the region of A orthogonally projected on an xy plane coincides with at least a portion of the region of B orthogonally projected on the xy plane. The expression “A is disposed between B and C” refers to a situation in which at least one of the line segments each connecting any given point within B to any given point within C passes through A.

Terms describing relationships between elements, such as “parallel” and “vertical”, terms indicating an element's shape, such as “rectangular”, and numerical ranges are not meant to convey only precise meanings. These terms and numerical ranges denote meanings that are substantially the same, involving, for example, about several percent differences.

### First Exemplary Embodiment

The following describes a communication device according to a first embodiment with reference to the drawings.

### [1.1 Circuit Configuration]

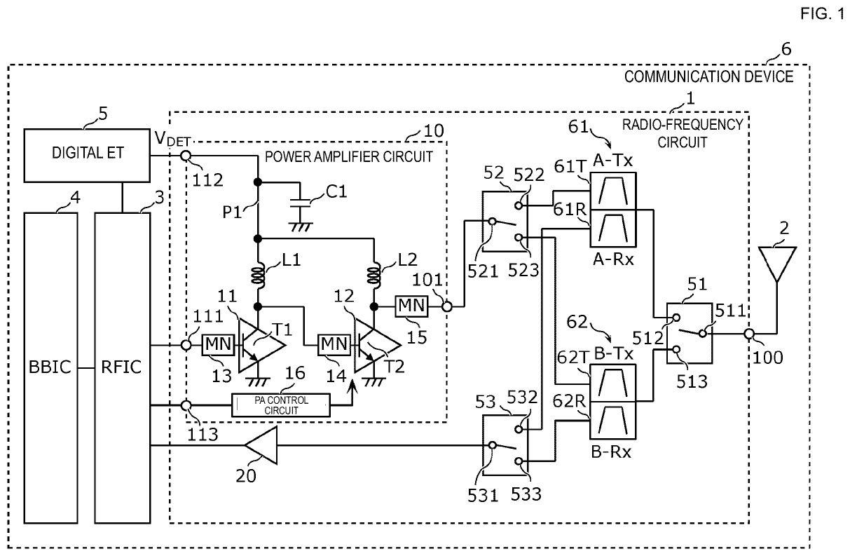

A circuit configuration of a communication device 6, a radio-frequency circuit 1, and a power amplifier circuit 10 according to the present exemplary embodiment will be described with reference to FIG. 1. FIG. 1 is a circuit configuration diagram of the communication device 6 according to the present exemplary embodiment.

### [1.1.1 Circuit Configuration of Communication Device 6]

First, a circuit configuration of the communication device 6 will be described. As illustrated in FIG. 1, the communication device 6 according to the present exemplary embodiment includes the radio-frequency circuit 1, an antenna 2, a radio-frequency integrated circuit (RFIC) 3, and a baseband integrated circuit (BBIC) 4, and a digital envelope tracker (digital ET) 5.

The radio-frequency circuit 1 is configured to transfer radio-frequency signals between the antenna 2 and the RFIC 3. The internal configuration of the radio-frequency circuit 1 will be described later.

The antenna 2 is coupled to an antenna connection terminal 100 of the radio-frequency circuit 1. The antenna 2 is configured to transmit radio-frequency signals output from the radio-frequency circuit 1. The antenna 2 is also configured to receive radio-frequency signals from outside and output the radio-frequency signals to the radio-frequency circuit 1.

The RFIC 3 is an example of a signal processing circuit for processing radio-frequency signals. According to an exemplary aspect, the RFIC 3 is configured to process, for example by down-conversion, radio-frequency receive signals inputted through receive paths of the radio-frequency circuit 1 and output the receive signals generated by the signal processing to the BBIC 4. The RFIC 3 is also configured to process, for example by up-conversion, transmit signals inputted from the BBIC 4 and output the radio-frequency transmit signals generated by the signal processing to transmit paths of the radio-frequency circuit 1. The RFIC 3 includes a control unit for controlling the radio-frequency circuit 1 and the digital ET 5. In some exemplary embodiments, the function of the control unit of the RFIC 3 is partially or entirely implemented outside the RFIC 3; for example, the function of the control unit of the RFIC 3 is implemented in the BBIC 4 or the radio-frequency circuit 1.

The BBIC 4 is a baseband signal processing circuit designed to perform signal processing using an intermediate frequency band that is lower than radio-frequency signals transferred by the radio-frequency circuit 1. Signals such as image signals for image display and/or sound signals for calls through speakers are used as signals to be processed by the BBIC 4.

The digital ET 5 is configured to supply a supply voltage V_{DET} (a first supply voltage) to the power amplifier circuit 10 in digital ET mode. According to an exemplary aspect, the supply voltage V_{DET} supplied by the digital ET 5 can be used to track the envelope of radio-frequency signals based on envelope signals. This supply voltage V_{DET} can vary across multiple discrete voltage levels.

For example, using pre-prepared multiple discrete voltages, the digital ET 5 can selectively output at least one of the pre-prepared discrete voltages using a switch (not illustrated). With this configuration, the switch enables the digital ET 5 to rapidly change the voltage level of the supply voltage V_{DET} supplied to the power amplifier circuit 10. It may also be possible that the digital ET 5 does not use pre-prepared multiple discrete voltages and selectively output at least one of the pre-prepared discrete voltages using a switch. For example, the digital ET 5 may generate and output multiple discrete voltages as needed.

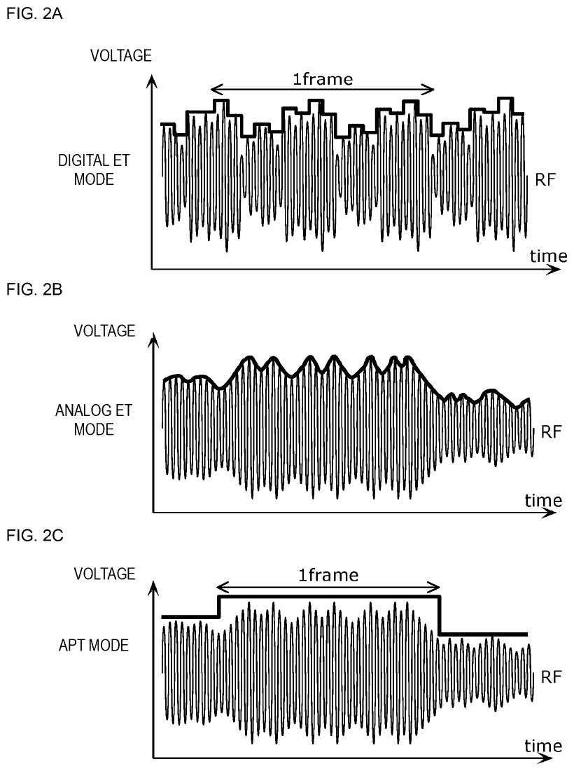

The envelope signal indicates the envelope value of modulated waves (radio-frequency signals). The envelope value is expressed as the square root of (I²+Q²), where (I, Q) represents the constellation point. The constellation point represents a signal modulated by digital modulation on the constellation diagram. Details of digital ET mode will be described later with reference to FIGS. 2A to 2C.

In addition to digital ET mode, the digital ET 5 is capable of supplying supply voltage in average power tracking (APT) mode and/or known ET mode (hereinafter referred to as analog ET mode).

The circuit configuration of the communication device 6 illustrated in FIG. 1 is provided for illustrative purposes, and this is not to be interpreted as limiting. For example, the communication device 6 does not necessarily include the antenna 2 and/or the BBIC 4. For example, the communication device 6 may include multiple antennas.

### [1.1.2 Circuit Configuration of Radio-Frequency Circuit 1]

Next, a circuit configuration of the radio-frequency circuit 1 will be described. As illustrated in FIG. 1, the radio-frequency circuit 1 includes the power amplifier circuit 10, a low-noise amplifier 20, switches 51 to 53, duplexers 61 and 62, and the antenna connection terminal 100. In the following, the constituent elements of the radio-frequency circuit 1 will be individually described.

The antenna connection terminal 100 is coupled to the switch 51 inside the radio-frequency circuit 1 and to the antenna 2 outside the radio-frequency circuit 1. The transmit signals in bands A and B amplified by the power amplifier circuit 10 can be output to the antenna 2 through the antenna connection terminal 100. The receive signals in the bands A and B received by the antenna 2 can be input to the radio-frequency circuit 1 through the antenna connection terminal 100.

The power amplifier circuit 10 is able to amplify transmit signals in the bands A and B. The internal configuration of the power amplifier circuit 10 will be described later.

The low-noise amplifier 20 is able to amplify receive signals in the bands A and B. The input end of the low-noise amplifier 20 is coupled to the switch 53, and the output end of the low-noise amplifier 20 is coupled to the RFIC 3 via an external connection terminal (not illustrated).

The switch h 51 is coupled between the antenna connection terminal 100 and the duplexers 61 and 62. The switch 51 has terminals 511 to 513. The terminal 511 is coupled to the antenna connection terminal 100. The terminal 512 is coupled to the duplexer 61. The terminal 513 is coupled to the duplexer 62.

With this connection configuration, the switch 51 is configured to connect the terminal 511 to the terminal 512 or 513 in response to, for example, a control signal from the RFIC 3. In other words, the switch 51 can switch connection of the antenna connection terminal 100 between the duplexers 61 and 62. The switch 51 is implemented by, for example, a single-pole double-throw (SPDT) switching circuit.

The switch 52 is coupled between transmit filters 61T and 62T and the power amplifier circuit 10. The switch 52 has terminals 521 to 523. The terminal 521 is coupled to the power amplifier circuit 10. The terminal 522 is coupled to the transmit filter 61T. The terminal 523 is coupled to the transmit filter 62T.

With this connection configuration, the switch 52 is configured to connect the terminal 521 to the terminal 522 or 523 in response to, for example, a control signal from the RFIC 3. In other words, the switch 52 is configured to switch connection of the power amplifier circuit 10 between the transmit filters 61T and 62T. The switch 52 is implemented by, for example, an SPDT switching circuit.

The switch 53 is coupled between receive filters 61R and 62R and the low-noise amplifier 20. The switch 53 has terminals 531 to 533. The terminal 531 is coupled to the low-noise amplifier 20. The terminal 532 is coupled to the receive filter 61R. The terminal 533 is coupled to the receive filter 62R.

With this connection configuration, the switch 53 is configured to connect the terminal 531 to the terminal 532 or 533 in response to, for example, a control signal from the RFIC 3. In other words, the switch 53 is configured to switch connection of the low-noise amplifier 20 between the receive filters 61R and 62R. The switch 53 is implemented by, for example, an SPDT switching circuit.

The duplexer 61 has a pass band that includes the band A. The duplexer 61 includes the transmit filter 61T and the receive filter 61R. The duplexer 61 implements frequency division duplex (FDD) within the band A.

The transmit filter 61T (A-Tx) is coupled between the power amplifier circuit 10 and the antenna connection terminal 100. According to an exemplary aspect, one end of the transmit filter 61T is coupled to the power amplifier circuit 10 via the switch 52. The other end of the transmit filter 61T is coupled to the antenna connection terminal 100 via the switch 51. The transmit filter 61T has a pass band that includes an uplink operating band of the band A. The transmit filter 61T is thus configured to pass transmit signals in the band A out of the transmit signals amplified by the power amplifier circuit 10.

The receive filter 61R (A-Rx) is coupled between the low-noise amplifier 20 and the antenna connection terminal 100. According to an exemplary aspect, one end of the receive filter 61R is coupled to the antenna connection terminal 100 via the switch 51. The other end of the receive filter 61R is coupled to the low-noise amplifier 20 via the switch 53. The receive filter 61R has a pass band that includes a downlink operating band of the band A. The receive filter 61R is thus configured to pass receive signals in the band A out of the receive signals received by the antenna 2.

The duplexer 62 has a pass band that includes the band B. The duplexer 62 includes the transmit filter 62T and the receive filter 62R. The duplexer 62 implements FDD within the band B.

The transmit filter 62T (B-Tx) is coupled between the power amplifier circuit 10 and the antenna connection terminal 100. According to an exemplary aspect, one end of the transmit filter 62T is coupled to the power amplifier circuit 10 via the switch 52. The other end of the transmit filter 62T is coupled to the antenna connection terminal 100 via the switch 51. The transmit filter 62T has a pass band that includes an uplink operating band of the band B. The transmit filter 62T is thus configured to pass transmit signals in the band B out of the transmit signals amplified by the power amplifier circuit 10.

The receive filter 62R (B-Rx) is coupled between the low-noise amplifier 20 and the antenna connection terminal 100. According to an exemplary aspect, one end of the receive filter 62R is coupled to the antenna connection terminal 100 via the switch 51. The other end of the receive filter 62R is coupled to the low-noise amplifier 20 via the switch 53. The receive filter 62R has a pass band that includes a downlink operating band of the band B. The receive filter 62R is thus configured to pass receive signals in the band B out of the receive signals received by the antenna 2.

The bands A and B correspond to frequency bands for communication systems built using a radio access technology (RAT). The bands A and B are defined by standardization organizations such as the 3rd Generation Partnership Project (3GPP) (registered trademark) and the Institute of Electrical and Electronics Engineers (IEEE). Examples of communication systems include a 5GNR system, an LTE system, and a Wireless Local Area Network (WLAN) system.

The radio-frequency circuit 1 depicted in FIG. 1 is illustrative, and this is not to be interpreted as limiting. For example, it is possible that the radio-frequency circuit 1 does not include either the duplexer 61 or 62. It may also be possible that the radio-frequency circuit 1 does not include the switches 51 to 53. It may also be possible that the radio-frequency circuit 1 does not include the receive path. It may also be possible that the radio-frequency circuit 1 does not include the receive filters 61R and 62R, the low-noise amplifier 20, and the switch 53. For example, the radio-frequency circuit 1 may include a filter and a power amplifier circuit that support a band C, which is different from the bands A and B.

### [1.1.3 Circuit Configuration of Power Amplifier Circuit 10]

Next, a circuit configuration of the power amplifier circuit 10 will be described. As illustrated in FIG. 1, the power amplifier circuit 10 includes power amplifiers 11 and 12, inductors L1 and L2, a bypass capacitor C1, matching circuits (matching networks: MN) 13 to 15, a power amplifier (PA) control circuit 16, an external output terminal 101, an external input terminal 111, a supply voltage terminal 112, and a control terminal 113. In the following, the constituent elements of the power amplifier circuit 10 will be individually described.

The external input terminal 111 is designed to receive transmit signals in the bands A and B from outside the power amplifier circuit 10. The external input terminal 111 is coupled to the RFIC3 outside the power amplifier circuit 10 and to a base terminal of the power amplifier 11 via the matching circuit 13 inside the power amplifier circuit 10. With this configuration, the transmit signals in the bands A and B received from the RFIC 3 through the external input terminal 111 can be supplied to the base terminal of the power amplifier 11.

The supply voltage terminal 112 is designed to receive the supply voltage V_{DET} from the digital ET 5. The supply voltage terminal 112 is coupled to the digital ET 5 outside the power amplifier circuit 10 and to collector terminals of the power amplifiers 11 and 12 via the inductors L1 and L2 inside the power amplifier circuit 10. With this configuration, the supply voltage V_{DET} received from the digital ET 5 through the supply voltage terminal 112 can be supplied to the collector terminals of the power amplifiers 11 and 12.

The control terminal 113 is designed to transfer control signals. According to an exemplary aspect, the control terminal 113 is designed to receive control signals from outside the power amplifier circuit 10 and/or to supply control signals to outside the power amplifier circuit 10.

The power amplifier 11 includes an amplifier transistor T1. The power amplifier 11 is continuously coupled to the power amplifier 12. The power amplifier 11 is provided in the stage (drive stage) before the power amplifier 12.

In the present exemplary embodiment, the amplifier transistor T1 is a bipolar transistor with a base terminal, a collector terminal, and an emitter terminal. The base terminal of the amplifier transistor T1 is coupled to the external input terminal 111 via the matching circuit 13. The collector terminal of the amplifier transistor T1 is coupled to the supply voltage terminal 112 via the inductor L1 and to the input end of the power amplifier 12 via the matching circuit 14. The emitter terminal of the amplifier transistor T1 is grounded.

This configuration enables the power amplifier 11 to amplify the radio-frequency signals input from the external input terminal 111 and to output the amplified radio-frequency signals to the power amplifier 12.

The power amplifier 12 includes an amplifier transistor T2. The power amplifier 12 is provided in the stage (power stage) after the power amplifier 11.

In the present exemplary embodiment, the amplifier transistor T2 is a bipolar transistor with a base terminal, a collector terminal, and an emitter terminal. The base terminal of the amplifier transistor T2 is coupled to the output end of the power amplifier 11 via the matching circuit 14. The collector terminal of the amplifier transistor T2 is coupled to the supply voltage terminal 112 via the inductor L2 and to the external output terminal 101 via the matching circuit 15. The emitter terminal of the amplifier transistor T2 is grounded.

This configuration enables the power amplifier 12 to further amplify the radio-frequency signals amplified by the power amplifier 11 and to output the amplified radio-frequency signals to the external output terminal 101.

The inductor L1 is coupled in series to a supply voltage path P1 that connects the supply voltage terminal 112 to the power amplifiers 11 and 12. The inductor L1 is a choke inductor. According to an exemplary aspect, the two ends of the inductor L1 are respectively coupled to the collector terminal of the amplifier transistor T1 and the supply voltage terminal 112.

The inductor L2 is coupled in series to the supply voltage path P1. The inductor L2 is a choke inductor. According to an exemplary aspect, the two ends of the inductor L2 are respectively coupled to the collector terminal of the amplifier transistor T2 and the supply voltage terminal 112.

The bypass capacitor C1 is an example of a first bypass capacitor. The bypass capacitor C1 is coupled between ground and the supply voltage path P1 connecting the supply voltage terminal 112 to the power amplifiers 11 and 12. According to an exemplary aspect, the bypass capacitor C1 has two terminals that are respectively coupled to ground and the supply voltage path P1.

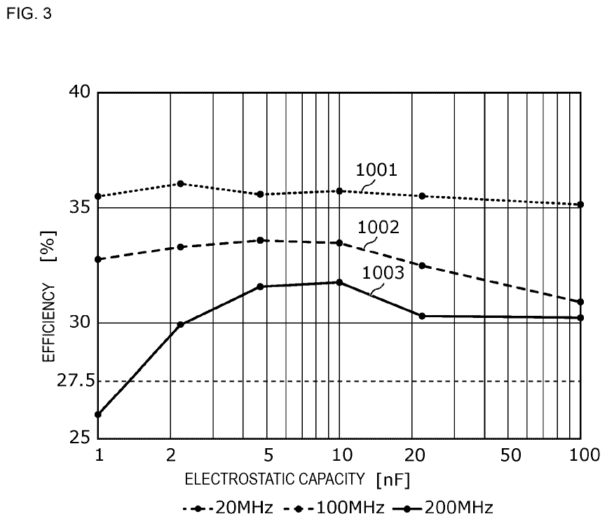

In some exemplary embodiments, the electrostatic capacity of the bypass capacitor C1 is equal to or higher than 1.4 nanofarads. In some exemplary embodiments the electrostatic capacity of the bypass capacitor C1 is equal to or higher than 5 nanofarads. In some exemplary embodiments, the electrostatic capacity of the bypass capacitor C1 is equal to or lower than 20 nanofarads. In some exemplary embodiments, the electrostatic capacity of the bypass capacitor C1 is equal to or lower than 10 nanofarads. The reasons for setting these electrostatic capacities will be described later with reference to FIG. 3.

The electrostatic capacity of capacitor can be measured using an LCR meter. The automatic balancing bridge method can be used for measurement.

The matching circuit 13 includes, for example, an inductor and/or a capacitor. The matching circuit 13 is coupled between the external input terminal 111 and the input end of the power amplifier 11. The matching circuit 13 is configured to provide impedance matching between the external input terminal 111 and the power amplifier 11.

The matching circuit 14 includes, for example, an inductor and/or a capacitor. The matching circuit 14 is coupled between the output end of the power amplifier 11 and the input end of the power amplifier 12. The matching circuit 14 is configured to provide impedance matching between the power amplifiers 11 and 12.

The matching circuit 15 includes, for example, an inductor and/or a capacitor. The matching circuit 15 is coupled between the output end of the power amplifier 12 and the external output terminal 101. The matching circuit 15 is configured to provide impedance matching between the power amplifier 12 and the external output terminal 101.

The PA control circuit 16 is a power amplifier controller (PAC) designed to control the power amplifiers 11 and 12. The PA control circuit 16 is configured to, for example, control the individual bias currents supplied to the base terminals of the amplifier transistors T1 and T2. It is noted that the PA control circuit 16 is not necessarily included in the power amplifier circuit 10.

In the power amplifier circuit 10 according to the present exemplary embodiment, the inductors L1 and L2 and the matching circuits 13 to 16 are non-essential constituent elements and can be removed or substituted with other circuit elements, for example, as required by the specifications of the power amplifier circuit 10.

In some exemplary embodiments, an inductor, capacitor, or resistor can be inserted in the power amplifier circuit 10 as needed. For example, an inductor is inserted between ground and the emitter terminal of the amplifier transistor T1 and/or the emitter terminal of the amplifier transistor T2.

It is possible that either the power amplifier 11 or 12 is not included in the power amplifier circuit 10. The power amplifier circuit 10 may include at least one additional power amplifier in addition to the power amplifiers 11 and 12. In this case, the at least one power amplifier is continuously coupled to the power amplifier 11 or 12 or in parallel with the power amplifier 11 or 12.

### [1.2 Explanation of Digital ET Mode]

Here, digital ET mode, along with analog ET mode and APT mode, will be described with reference to FIGS. 2A to 2C. FIG. 2A is a graph illustrating an example of supply voltage variations in digital ET mode. FIG. 2B is a graph illustrating an example of supply voltage variations in analog ET mode. FIG. 2C is a graph illustrating an example of supply voltage variations in APT mode. In FIGS. 2A to 2C, the horizontal axis represents time, and the vertical axis represents voltage. The thick solid line represents the supply voltage, and the thin solid line (waveform) represents the modulated wave.

In digital ET mode, as illustrated in FIG. 2A, the envelope of a modulated wave is tracked by varying the supply voltage among multiple discrete voltage levels within a single frame. As a result, the supply voltage signal exhibits square waves. In digital ET mode, at least one among multiple discrete voltages can be selected or set, based on the envelope signal.

According to an exemplary aspect, the term “frame” refers to a unit that forms a radio-frequency signal (a modulated wave). For example, in 5th Generation New Radio (5GNR) and Long Term Evolution (LTE), a frame comprises ten subframes. Each subframe consists of multiple slots, and each slot includes multiple symbols. The subframe length is 1 ms, and the frame length is 10 ms.

In analog ET mode, as illustrated in FIG. 2B, the envelope of a modulated wave is tracked by continuously varying the supply voltage. In analog ET mode, the supply voltage is determined based on the envelope signal. In analog ET mode, tracking the envelope using the supply voltage becomes difficult when the modulated wave's envelope changes at high speed.

In APT mode, as illustrated in FIG. 2C, the supply voltage varies across multiple discrete voltage levels in single-frame units, based on the average power. As a result, the supply voltage signal exhibits square waves. In APT mode, the supply voltage level is determined based on the average output power, instead of the envelope signal. In APT mode, the voltage level may change in units smaller than single-frame units (for example, subframes).

### [1.3 Relationship Between Efficiency of Power Amplifier Circuit 10 and Electrostatic Capacity of Bypass Capacitor C1]

Next, the relationship between the efficiency of the power amplifier circuit 10 and the electrostatic capacity of the bypass capacitor C1 in the present exemplary embodiment will be described with reference to FIG. 3. FIG. 3 is a graph illustrating the relationship between the electrostatic capacity of the bypass capacitor C1 and the efficiency of the power amplifier circuit 10 in the present exemplary embodiment. According to an exemplary aspect, the graph in FIG. 3 illustrates the relationship between the efficiency of the power amplifier circuit 10 with digital ET mode applied and the electrostatic capacity of the bypass capacitor C1.

In FIG. 3, the vertical axis represents the efficiency of the power amplifier circuit 10, and the horizontal axis represents the electrostatic capacity of the bypass capacitor C1. A data series 1001 illustrates the relationship between efficiency and electrostatic capacity when the channel band width of radio-frequency signals is 20 MHz. A data series 1002 illustrates the relationship between efficiency and electrostatic capacity when the channel band width of radio-frequency signals is 100 MHz. A data series 1003 illustrates the relationship between efficiency and electrostatic capacity when the channel band width of radio-frequency signals is 200 MHz. The efficiency (27.5%) of the power amplifier circuit 10 with APT mode applied is illustrated by a dashed line in FIG. 3.

When the electrostatic capacity of the bypass capacitor C1 is below 1.4 nanofarads, the efficiency of the power amplifier circuit 10 with digital ET mode applied at the 200 MHz channel band width (the data series 1003) falls below the efficiency of the power amplifier circuit 10 in the APT mode (27.5%). When the electrostatic capacity of the bypass capacitor C1 is equal to or higher than 1.4 nanofarads, the efficiency of the power amplifier circuit 10 in digital ET mode applied across all channel band widths (the data series 1001 to 1003) exceeds the efficiency of the power amplifier circuit 10 in the APT mode (27.5%). Therefore, it is desirable for the electrostatic capacity of the bypass capacitor C1 to be equal to or higher than 1.4 nanofarads.

In particular, using analog ET mode becomes difficult with wider channel band widths (for example, 200 MHz), because envelope signal variations are faster in these wider channel band widths. In these situations, when the efficiency in digital ET mode is higher than the efficiency in APT mode, applications with higher efficiency than the efficiency possible with APT mode can be realized. Therefore, using the bypass capacitor C1 with an electrostatic capacity equal to or higher than 1.4 nanofarads in digital ET mode is significantly effective in improving efficiency across wide channel band widths.

Furthermore, at the 200 MHz channel band width, the efficiency increase rate (slope) with increasing electrostatic capacity is relatively high for electrostatic capacities below 5 nanofarads; and the efficiency increase rate with increasing electrostatic capacity is relatively low for electrostatic capacities equal to or higher than 5 nanofarads. This means that the efficiency of the power amplifier circuit 10 can be effectively improved by increasing the bypass capacitor electrostatic capacity to up to 5 nanofarads. Hence, when the 200 MHz channel band width for radio-frequency signals is used, it is desirable for the electrostatic capacity of the bypass capacitor C1 to be equal to or higher than 5 nanofarads.

Further, at any channel band width, no efficiency improvement can be expected with electrostatic capacities exceeding 20 nanofarads. Therefore, it is desirable for the electrostatic capacity of the bypass capacitor C1 to be equal to or lower than 20 nanofarads.

Furthermore, at the 200 MHz channel band width, efficiency decreases as electrostatic capacity increases beyond 10 nanofarads. Hence, when the 200 MHz channel band width for radio-frequency signals is used, it is desirable for the electrostatic capacity of the bypass capacitor C1 to be equal to or lower than 10 nanofarads.

### [1.4 Effects]

As described above, the power amplifier circuit 10 according to the present exemplary embodiment includes the power amplifiers 11 and/or 12 configured to amplify radio-frequency signals, the supply voltage terminal 112 coupled to the power amplifiers 11 and/or 12, and the bypass capacitor C1 coupled between ground and the supply voltage path P1 connecting the supply voltage terminal 112 to the power amplifiers 11 and/or 12. The supply voltage V_{DET} is configured to be supplied to the power amplifiers 11 and/or 12 through the supply voltage terminal 112, and the supply voltage V_{DET} is configured to vary across multiple discrete voltage levels within a single frame of radio-frequency signals. The bypass capacitor C1 has an electrostatic capacity equal to or higher than 1.4 nanofarads.

In an aspect, the power amplifier circuit 10 according to the present exemplary embodiment includes the power amplifiers 11 and/or 12 configured to amplify radio-frequency signals, the supply voltage terminal 112 coupled to the digital ET 5, and the bypass capacitor C1 coupled between ground and the supply voltage path P1 connecting the supply voltage terminal 112 to the power amplifiers 11 and/or 12. The bypass capacitor C1 has an electrostatic capacity equal to or higher than 1.4 nanofarads.

This configuration improves the efficiency of the power amplifier circuit 10 with digital ET mode applied beyond the efficiency of the power amplifier circuit in APT mode across all channel band widths, as described with reference to FIG. 3.

In an example, in the power amplifier circuit 10 according to the exemplary embodiment, it is desirable that the bypass capacitor C1 has an electrostatic capacity equal to or higher than 5 nanofarads.

This configuration improves the efficiency of the power amplifier circuit 10, particularly for amplifying radio-frequency signals within the 200 MHz channel band width, as described with reference to FIG. 3.

In an example, in the power amplifier circuit 10 according to the exemplary embodiment, the bypass capacitor C1 may have an electrostatic capacity equal to or lower than 20 nanofarads.

This configuration suppresses an unnecessary increase in the electrostatic capacity of the bypass capacitor C1, which does not contribute to efficiency improvement across any channel band widths, as described with reference to FIG. 3.

In an example, in the power amplifier circuit 10 according to the exemplary embodiment, it is desirable that the bypass capacitor C1 has an electrostatic capacity equal to or lower than 10 nanofarads.

This configuration suppresses the decrease in the efficiency of the power amplifier circuit 10 at the 200 MHZ channel band width, as described with reference to FIG. 3.

### Second Exemplary Embodiment

Next, a second embodiment will be described. The present exemplary embodiment differs from the first embodiment primarily in that digital ET mode or analog ET mode is selectively applied to the power amplifier circuit, and switching between bypass capacitors is performed according to the applied mode. In the following, the present exemplary embodiment will be described with reference to the drawings, focusing primarily on features that differ from the first embodiment.

### [2.1 Circuit Configuration]

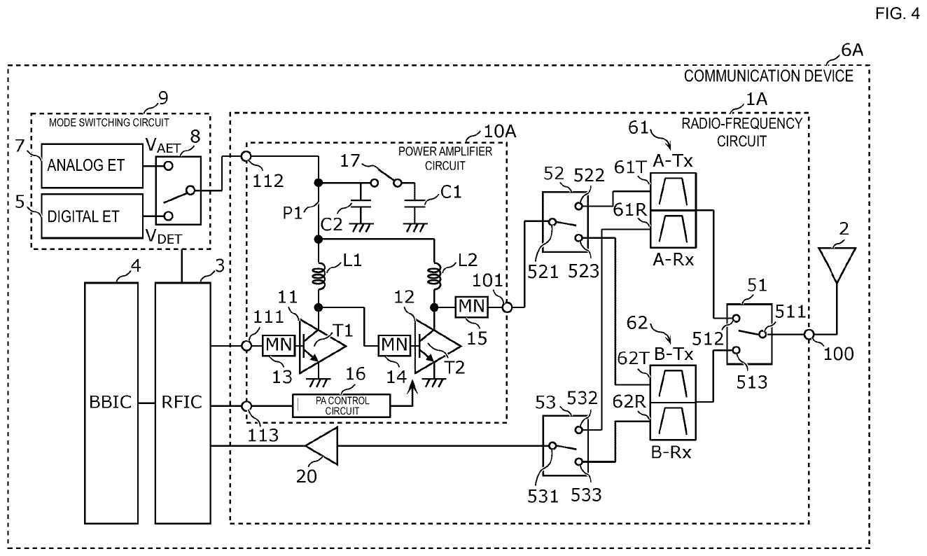

A circuit configuration of a communication device 6A, a radio-frequency circuit 1A, and a power amplifier circuit 10A according to the present exemplary embodiment will be described with reference to FIG. 4. FIG. 4 is a circuit configuration diagram of the communication device 6A according to the present exemplary embodiment.

### [2.1.1 Circuit Configuration of Communication Device 6A]

The communication device 6A includes a radio-frequency circuit 1A, an antenna 2, an RFIC 3, a BBIC 4, and a mode switching circuit 9.

The radio-frequency circuit 1A is configured to transfer radio-frequency signals between the antenna 2 and the RFIC 3. The internal configuration of the radio-frequency circuit 1A will be described later.

The mode switching circuit 9 is configured to switch between digital ET mode and analog ET mode. As illustrated in FIG. 4, the mode switching circuit 9 includes a digital ET 5, an analog envelope tracker (analog ET) 7, and a switch 8.

The analog ET 7 is configured to supply a supply voltage V_{AET} (a second supply voltage) to the power amplifier circuit 10A in analog ET mode. According to an exemplary aspect, the supply voltage V_{AET} supplied by the analog ET 7 can be used to track the envelope of radio-frequency signals based on envelope signals.

The supply voltage V_{AET} can vary continuously in voltage level.

The switch 8 is coupled between the digital ET 5 and the analog ET 7, and the power amplifier circuit 10A. The switch 8 is configured to selectively couple the digital ET 5 or the analog ET 7 to the power amplifier circuit 10A in response to a control signal from the RFIC 3. When the digital ET 5 is coupled to the power amplifier circuit 10A, the supply voltage V_{DET} can be supplied in digital ET mode to the power amplifiers 11 and 12. When the analog ET 7 is coupled to the power amplifier circuit 10A, the supply voltage V_{AET} Can be supplied in analog ET mode to the power amplifiers 11 and 12.

### [2.1.2 Circuit Configuration of Radio-Frequency Circuit 1A]

The circuit configuration of the radio-frequency circuit 1A is the same as the radio-frequency circuit 1 of the first embodiment, except that the power amplifier circuit 10A is included in place of the power amplifier circuit 10. Thus, descriptions thereof are not repeated.

### [2.1.3 Circuit Configuration of Power Amplifier Circuit 10A]

Next, a circuit configuration of the power amplifier circuit 10A will be described. As illustrated in FIG. 4, in the power amplifier circuit 10A, a switch 17 and a bypass capacitor C2 are added to the power amplifier circuit 10 according to the first embodiment. In the following, the additional constituent elements in the power amplifier circuit 10A will be individually described.

The switch 17 is coupled between a supply voltage path P1 and a bypass capacitor C1. With this configuration, the switch 17 is configured to control connection and disconnection between the bypass capacitor C1 and the supply voltage path P1.

According to an exemplary aspect, when the supply voltage V_{DET} is supplied to the power amplifiers 11 and 12, in other words, when the digital ET 5 is coupled to the power amplifiers 11 and 12, the switch 17 couples the bypass capacitor C1 to the supply voltage path P1. By contrast, when the supply voltage V_{AET} is supplied to the power amplifiers 11 and 12, in other words, when the analog ET 7 is coupled to power amplifiers 11 and 12, the switch 17 does not couple the bypass capacitor C1 to the supply voltage path P1.

As a switching condition for the switch 17, the channel band width of radio-frequency signals is used. For example, it is possible that when the supply voltage V_{DET} is supplied to the power amplifiers 11 and 12 and the channel band width of radio-frequency signals is equal to or greater than a predetermined band width, the switch 17 couples the bypass capacitor C1 to the supply voltage path P1. By contrast, it is possible that when the supply voltage V_{AET} is supplied to the power amplifiers 11 and 12, or when the supply voltage V_{DET} is supplied to the power amplifiers 11 and 12 and the channel band width of radio-frequency signals is smaller than the predetermined band width, the switch 17 does not couple the bypass capacitor C1 to the supply voltage path P1.

As the predetermined band width, a band width empirically and/or experimentally predetermined can be used. For example, 100 MHz is used as the predetermined band width.

The bypass capacitor C2 is an example of a second bypass capacitor. The bypass capacitor C2 is coupled between ground and the supply voltage path P1. In the present exemplary embodiment, the bypass capacitor C2 is coupled to the supply voltage path P1 without involving the switch 17. The electrostatic capacity of the bypass capacitor C2 is lower than the electrostatic capacity of the bypass capacitor C1. As the bypass capacitor C2, a capacitor with an electrostatic capacity in the order of picofarads can be used. More specifically, for example, a capacitor with an electrostatic capacity of 100 picofarads is used as the bypass capacitor C2.

### [2.2 Technical Effects]

As described above, the power amplifier circuit 10A according to the present exemplary embodiment may include the switch 17 that is coupled between the supply voltage path P1 and the bypass capacitor C1, and the bypass capacitor C2 that is coupled between ground and the supply voltage path P1 and that has an electrostatic capacity lower than the electrostatic capacity of the bypass capacitor C1.

With this configuration, the switch 17 is configured to control connection and disconnection between the bypass capacitor C1, which has a relatively high electrostatic capacity, and the supply voltage path P1.

In an example, in the power amplifier circuit 10A according to the present exemplary embodiment, the supply voltage V_{DET} and the supply voltage V_{AET} is configured such that the supply voltage V_{DET} or the supply voltage V_{AET} is selectively supplied to the power amplifiers 11 and/or 12 through the supply voltage terminal 112; and the switch 17 is configured to, when the supply voltage V_{DET} is supplied to the power amplifiers 11 and/or 12, couple the bypass capacitor C1 to the supply voltage path P1, and when the supply voltage V_{AET} iS supplied to the power amplifiers 11 and/or 12, not couple the bypass capacitor C1 to the supply voltage path P1.

In other words, in the power amplifier circuit 10A according to the present exemplary embodiment, the digital ET5 or the analog ET7 is selectively coupled to the power amplifiers 11 and/or 12 through the supply voltage terminal 112; and the switch 17 is configured to, when the digital ET 5 is coupled to the power amplifiers 11 and/or 12, couple the bypass capacitor C1 to the supply voltage path P1, and when the analog ET 7 is coupled to the power amplifiers 11 and/or 12, not couple the bypass capacitor C1 to the supply voltage path P1.

With this configuration, when the supply voltage V_{DET} is supplied to the power amplifiers 11 and/or 12, in other words, when the digital ET 5 is coupled to the power amplifiers 11 and/or 12, the bypass capacitor C1, which has a relatively high electrostatic capacity, is coupled to the supply voltage path P1. This configuration improves the efficiency of the power amplifier circuit 10A in digital ET mode. By contrast, when the supply voltage V_{AET} is supplied to the power amplifiers 11 and/or 12, in other words, when the analog ET 7 is coupled to the power amplifiers 11 and/or 12, the bypass capacitor C1, which has a relatively high electrostatic capacity, is not coupled to the supply voltage path P1. This configuration reduces the delay in the variation of the supply voltage V_{AET} supplied to the power amplifiers 11 and/or 12, relative to the time variation in the envelope signal in analog ET mode. In other words, this configuration helps prevent degradation in tracking performance in analog ET mode. As such, output signal distortions in the power amplifier circuit 10A can be reduced. The efficiency reduction is relatively small as compared to the electrostatic capacity reduction in the bypass capacitor in analog ET mode. Consequently, the reduction in efficiency of the power amplifier circuit 10A can also be minimized.

In an example, in the power amplifier circuit 10A according to the present exemplary embodiment, the supply voltage V_{DET} and the supply voltage V_{AET} is configured such that the supply voltage V_{DET} or the supply voltage V_{AET} is selectively supplied to the power amplifiers 11 and/or 12 through the supply voltage terminal 112; and the switch 17 is configured to, when the supply voltage V_{DET} is supplied to the power amplifiers 11 and/or 12 and the channel band width of radio-frequency signals is equal to or greater than a predetermined band width, couple the bypass capacitor C1 to the supply voltage path P1, and when the supply voltage V_{AET} is supplied to the power amplifiers 11 and/or 12, or when the supply voltage V_{DET} is supplied to the power amplifiers 11 and/or 12 and the channel band width of radio-frequency signals is smaller than the predetermined band width, not couple the bypass capacitor C1 to the supply voltage path P1.

In other words, in the power amplifier circuit 10A according to the present exemplary embodiment, the digital ET5 and the analog ET7 is configured such that the digital ET5 or the analog ET7 is selectively coupled to the power amplifiers 11 and/or 12 through the supply voltage terminal 112; and the switch 17 is configured to, when the digital ET 5 is coupled to the power amplifiers 11 and/or 12 and the channel band width of radio-frequency signals is equal to or greater than a predetermined band width, couple the bypass capacitor C1 to the supply voltage path P1, and when the analog ET 7 is coupled to the power amplifiers 11 and/or 12, or when the digital ET 5 is coupled to the power amplifiers 11 and/or 12 and the channel band width of radio-frequency signals is smaller than the predetermined band width, not couple the bypass capacitor C1 to the supply voltage path P1.

With this configuration, when the channel band width of radio-frequency signals is relatively wide, as indicated by the data series 1003 in FIG. 3, the efficiency in digital ET mode is enhanced as compared to the efficiency in APT mode by coupling the bypass capacitor C1 to the supply voltage path P1. When the channel band width of radio-frequency signals is relatively narrow, as indicated by the data series 1001 and 1002 in FIG. 3, the bypass capacitor C1 is not coupled to the supply voltage path P1. This configuration maintains higher efficiency compared to the efficiency in APT mode, while helping preventing degradation in tracking performance.

### (Modification)

Next, a modification will be described. The present modification differs from the first and second embodiments primarily in that switching between two bypass capacitors with different electrostatic capacities is performed according to the channel band width. In the following, the application of the present modification to the second embodiment will be described with reference to the drawings, focusing primarily on features that differ from the second embodiment.

### [3.1 Circuit Configuration of Power Amplifier Circuit 10B]

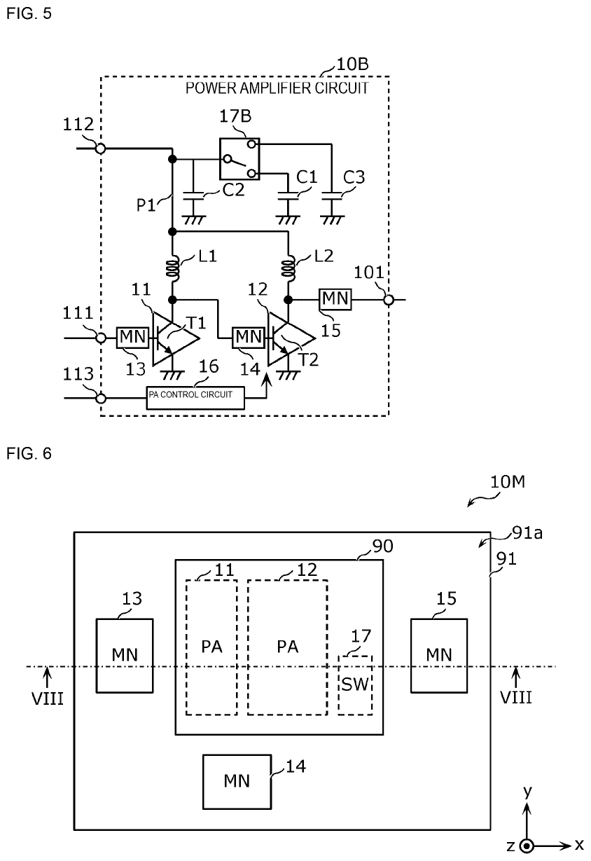

A circuit configuration of the power amplifier circuit 10B according to the present modification will be described. As illustrated in FIG. 5, in the power amplifier circuit 10B, the switch 17 is substituted with a switch 17B, and a bypass capacitor C3 is additionally incorporated. In the following, the substitute or additional constituent elements amplifier circuit 10B will be individually described.

The bypass capacitor C3 is an example of a third bypass capacitor. The bypass capacitor C3 is coupled between ground and the switch 17B. This means that the bypass capacitor C3 is coupled to the supply voltage path P1 via the switch 17B. The electrostatic capacity of the bypass capacitor C3 is different from the electrostatic capacity of the bypass capacitor C1. In the present modification, the electrostatic capacity of the bypass capacitor C3 is lower than the electrostatic capacity of the bypass capacitor C1 and higher than the electrostatic capacity of the bypass capacitor C2. For example, the electrostatic capacity of the bypass capacitor C3 is equal to or higher than 1.4 nanofarads and equal to or lower than 5 nanofarads. The electrostatic capacity of the bypass capacitor C3 is not limited to the above example.

The switch 17B is coupled between the supply voltage path P1 and the bypass capacitors C1 and C3. The switch 17B is configured to switch connection of the supply voltage path P1 between the bypass capacitors C1 and C3. For example, when the channel band width of radio-frequency signals is equal to or greater than a predetermined band width in digital ET mode, the switch 17B couples the bypass capacitor C1 to the supply voltage path P1 and does not couple the bypass capacitor C3 to the supply voltage path P1. When the channel band width of radio-frequency signals is smaller than the predetermined band width in digital ET mode, the switch 17B couples the bypass capacitor C3 to the supply voltage path P1 and does not couple the bypass capacitor C1 to the supply voltage path P1. In analog ET mode, the switch 17B does not couple the bypass capacitors C1 and C3 to the supply voltage path P1.

The bypass capacitors C1 and C3 and the switch 17B are substituted with variable capacitors. For example, digitally tunable capacitors (DTC) are used as variable capacitors. However, this is not to be interpreted as limiting.

### [3.2 Technical Effects]

As described above, the power amplifier circuit 10B according to the present exemplary embodiment may include the bypass capacitor C3 that is coupled between ground and the switch 17B and that has an electrostatic capacity different from the electrostatic capacity of the bypass capacitor C1. When the channel band width of radio-frequency signals is equal to or greater than a predetermined band width, the bypass capacitor C1 is coupled to the supply voltage path P1, and when the channel band width of radio-frequency signals is smaller than the predetermined band width, the bypass capacitor C3 is coupled to the supply voltage path P1.

With this configuration, the bypass capacitor C1 or C3, which have different electrostatic capacities, can be coupled to the supply voltage path P1 according to the channel band width. Consequently, a bypass capacitor with an electrostatic capacity suitable for the channel band width can be used. This configuration achieves a balance between improving the efficiency of the power amplifier circuit 10B and reducing output signal distortions in the power amplifier circuit 10B.

As described above, in the power amplifier circuit 10B according to the present exemplary embodiment, the bypass capacitor C3 may have an electrostatic capacity lower than the electrostatic capacity of the bypass capacitor C1 and higher than the electrostatic capacity of the bypass capacitor C2.

With this configuration, when the channel band width of radio-frequency signals is relatively wide, as indicated by the data series 1003 in FIG. 3, the efficiency in digital ET mode is enhanced by coupling the relatively higher bypass capacitor C1 (e.g., bypass capacitor with larger capacitance) to the supply voltage path P1. When the channel band width of radio-frequency signals is relatively narrow, as indicated by the data series 1001 and 1002 in FIG. 3, the bypass capacitor C3, which has a capacity lower than the capacity of the bypass capacitor C1, is coupled to the supply voltage path P1. This configuration maintains higher efficiency compared to the efficiency in APT mode, while helping preventing degradation in tracking performance.

The present modification can also be applied to the first embodiment. According to an exemplary aspect, the mode switching circuit 9 is substituted with the digital ET 5, and the bypass capacitor C2 is removed from the power amplifier circuit 10B.

In the second embodiment and the present the mode switching circuit 9 includes the modification, digital ET 5 and the analog ET 7. However, the mode switching circuit 9 may include an average power tracker, in addition to the digital ET 5 and the analog ET 7 or in place of the analog ET 7. In this case, APT mode is treated as digital ET mode when the channel band width of radio-frequency signals is relatively narrow.

### (Practical Example)

Next, a power amplifier module 10M will be described as a practical example of the power amplifier circuit 10A according to the second embodiment, with reference to FIGS. 6 to 8.

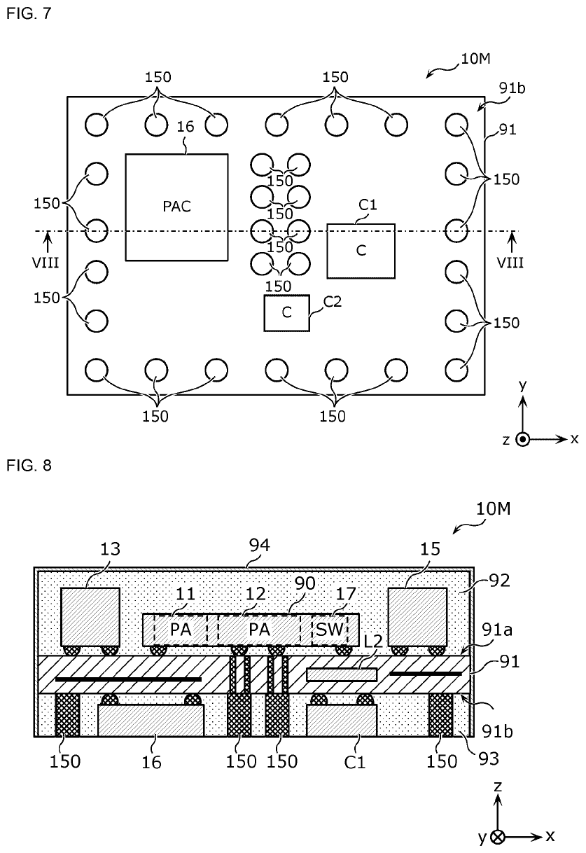

FIG. 6 is a plan view of the power amplifier module 10M according to the present practical example. FIG. 7 is a plan view of the power amplifier module 10M according to the present practical example when a major surface 91b side of a module substrate 91 is viewed through the module substrate 91 from the positive side of the z-axis. FIG. 8 is a sectional view of the power amplifier module 10M according to the present practical example. The section of the power amplifier module 10M in FIG. 8 is taken along line VIII-VIII in FIGS. 6 and 7.

In FIGS. 6 to 8, the wires connecting circuit components disposed at the module substrate 91 are not fully illustrated. In FIGS. 6 and 7, resin members 92 and 93 that cover multiple circuit components, and a shield electrode layer 94 are not illustrated. In FIGS. 6 to 8, for ease of understanding of the positional relationship among the circuit components, the individual circuit components are sometimes assigned corresponding abbreviations (for example, “PA”) representing the function of each circuit component, although the abbreviations are not displayed in the actual circuit components.

The module substrate 91 has major surfaces 91a and 91b that are opposite to each other. For example, wiring layers, via-conductors, and ground electrode layers are formed inside the module substrate 91. In FIGS. 6 and 7, the module substrate 91 has a rectangular shape in plan view. However, the module substrate 91 is not limited to this shape.

As the module substrate 91, for example, a low temperature co-fired ceramics (LTCC) substrate or high temperature co-fired ceramics (HTCC) substrate that has a layered structure composed of multiple dielectric layers, a component-embedded substrate, a substrate including a redistribution layer (RDL), or a printed-circuit board can be used. However, these are not to be interpreted as limiting.

At the major surface 91a, an integrated circuit 90, the matching circuits 13 to 15, and the resin member 92 are disposed.

The integrated circuit 90 includes the power amplifiers 11 and 12 and the switch 17. It is possible that the integrated circuit 90 includes the power amplifiers 11 and 12 but does not include the switch 17. It is possible that the integrated circuit 90 includes other circuit elements (for example, the bypass capacitors C1 and/or C2).

The integrated circuit 90 is made of, for example, at least one of gallium arsenide (GaAs), silicon germanium (SiGe), and gallium nitride (GaN). With this configuration, the power amplifiers 11 and 12 and other circuit components can be implemented with high quality. A portion of the power amplifiers 11 and 12, and the switch 17 is constructed using, for example, complementary metal oxide semiconductor (CMOS). According to an exemplary aspect, a portion of the power amplifiers 11 and 12, and the switch 17 is produced through a silicon on insulator (SOI) process. This configuration lowers the manufacturing cost of the integrated circuit 90.

Each of the matching circuits 13 to 15 is implemented by a chip inductor and/or a chip capacitor. A chip inductor is a surface mount device (SMD) that forms an inductor. A chip capacitor is an SMD that forms a capacitor. The matching circuits 13 to 15 are implemented by integrated passive devices (IPDs).

The resin member 92 at least partially covers the major surface 91a and the electronic components disposed at the major surface 91a. The resin member 92 functions to secure the reliability of mechanical strength, moisture resistance, and other properties of the electronic components disposed at the major surface 91a. The resin member 92, however, is not necessarily included in the power amplifier module 10M.

At the major surface 91b, the PA control circuit 16, the bypass capacitors C1 and C2, multiple post electrodes 150, and the resin member 93 are disposed.

The PA control circuit 16 is constructed using, for example, CMOS. According to an exemplary aspect, the PA control circuit 16 is produced through an SOI process. The PA control circuit 16 is not limited to CMOS.

The bypass capacitors C1 and C2 are implemented by chip capacitors. The bypass capacitors C1 and/or C2 are implemented by semiconductor components.

The post electrodes 150 serve as external connection terminals including ground terminals as well as the external output terminal 101, the external input terminal 111, the supply voltage terminal 112, and the control terminal 113 illustrated in FIG. 4. Copper electrodes can be used as the post electrodes 150. However, this is not to be interpreted as limiting. For example, multiple solder electrodes are used as the post electrodes. Multiple bump electrodes are used in place of the post electrodes 150 in some exemplary embodiments.

The resin member 93 at least partially covers the major surface 91b and the electronic components disposed at the major surface 91b. The resin member 93 functions to secure the reliability of mechanical strength, moisture resistance, and other properties of the electronic components disposed at the major surface 91b. The resin member 93, however, is not necessarily included in the radio-frequency circuit 1A.

The inductor L2 is disposed inside the module substrate 91. The inductor L2 is implemented by, for example, a wiring pattern inside the module substrate 91. The inductor L1, not illustrated in the drawing, is disposed inside the module substrate 91, similar to the inductor L2, or at the major surface 91a or 91b in some exemplary embodiments.

In the plan view of the module substrate 91, the bypass capacitor C1 overlaps the switch 17 inside the integrated circuit 90. The bypass capacitor C1 is coupled to the switch 17 through, for example, a via-conductor (not illustrated in the drawing) in the module substrate 91. This configuration shortens the wire length between the bypass capacitor C1 and the switch 17, thereby reducing the impedance, particularly inductance, of the wire between the bypass capacitor C1 and the power amplifiers 11 and 12. As a result, this configuration suppresses the degradation of the characteristics of the bypass capacitor C1 that can occur when the wire increases, thereby enhancing bypass capacitor noise reduction.

In the plan view of module substrate 91, the switch 17 inside the integrated circuit 90 overlaps the inductor L2. The switch 17 is coupled to the inductor L2 through, for example, a via-conductor (not illustrated in the drawing) in the module substrate 91. This configuration shortens the wire length between the switch 17 and the inductor L2, thereby reducing the impedance, particularly inductance, of the wire between the bypass capacitor C1 and the power amplifier 12. As a result, this configuration suppresses the degradation of the characteristics of the bypass capacitor C1 that can occur when the wire impedance increases, thereby enhancing bypass capacitor noise reduction.

The shield electrode layer 94 is, for example, a thin metal film that is formed using a sputtering method. The shield electrode layer 94 covers the upper surface of the resin member 92 and the side surfaces of the resin members 92 and 93 and the module substrate 91. According to an exemplary aspect, the shield electrode layer 94 is grounded to inhibit external noise from interfering with the electronic components forming the power amplifier module 10M. The shield electrode layer 94, however, is not necessarily included in the power amplifier module 10M.

The layout of the electronic components in the present practical example is illustrative, and the present practical example is not to be interpreted as limiting. For example, it is possible that the inductor L2 is not disposed inside the module substrate 91, but at the major surface 91a or 91b. The bypass capacitors C1 and/or C2 may be disposed at the major surface 91a. The power amplifier module 10M is integrated with a radio-frequency module that forms the radio-frequency circuit 1A in some exemplary embodiments.

The power amplifier circuit 10 according to the first embodiment and the power amplifier circuit 10B according to the modification can also be implemented based on the same concept as the power amplifier module 10M.

### Additional Exemplary Embodiments

The power amplifier circuits s according to the present disclosure have been described based on the exemplary embodiments and modification. However, the power amplifier circuits according to the present disclosure are not limited to the exemplary embodiments and modification. The present disclosure also embraces other embodiments implemented by any combination of the constituent elements of the embodiments and modification obtained by making various modifications to the embodiments and modification that occur to those skilled in the art without departing from the scope of the present disclosure, and various hardware devices including the power amplifier modules described above.

For example, in the circuit configuration of the power amplifier circuits, the radio-frequency circuits, and the communication devices according to the exemplary embodiments described above, other circuit elements and/or interconnections may also be inserted in the paths connecting the circuit elements and the signal paths that are illustrated in the drawings. For example, matching circuits are inserted between the switch 52 and the transmit filter 61T and/or between the switch 52 and the transmit filter 62T.

In the exemplary embodiments, the bands A and/or B represent bands for FDD, but the bands A and/or B are bands for time division duplex (TDD). In this case, the transmit filter and the receive filter are formed as a single filter.

The present disclosure can be used as power amplifier circuits provided at the front-end in a wide variety of communication devices such as mobile phones.

### REFERENCE SIGNS LIST

1, 1A radio-frequency circuit
2 antenna
3 RFIC
4 BBIC
5 digital ET
6, 6A communication device
7 analog ET
8, 17, 17B, 51, 52, 53 switch
9 mode switching circuit
10, 10A, 10B power amplifier circuit
10M power amplifier module
11, 12 power amplifier
13, 14, 15 matching circuit
16 PA control circuit
20 low-noise amplifier
61, 62 duplexer
61R, 62R receive filter
61T, 62T transmit filter
90 integrated circuit
91 module substrate
91a, 91b major surface
92, 93 resin member
94 shield electrode layer
100 antenna connection terminal
101 external output terminal
111 external input terminal
112 supply voltage terminal
113 control terminal
150 post electrode
C1, C2, C3 bypass capacitor
L1, L2 inductor
P1 supply voltage path
T1, T2 amplifier transistor
V_{AET}, V_{DET} supply voltage

1. A power amplifier circuit comprising:
a power amplifier configured to amplify a radio-frequency signal;
a supply voltage terminal coupled to the power amplifier via a supply voltage path that provides a supply voltage supplied at the supply voltage terminal to the power amplifier; and
a first bypass capacitor coupled between a ground and the supply voltage path, wherein:
a first supply voltage to be supplied to the supply voltage terminal is configured in a digital envelope tracking mode that tracks the radio-frequency signal and varies across a plurality of discrete voltage levels within a single frame of the radio-frequency signal; and
the first bypass capacitor has a first electrostatic capacity equal to or higher than a value that is determined to cause the power amplifier circuit with the first supply voltage being provided to the supply voltage terminal to have a higher efficiency than a threshold efficiency.

2. The power amplifier circuit according to claim 1, wherein the threshold efficiency corresponds to an efficiency of the power amplifier circuit in an average power tracking mode.

3. The power amplifier circuit according to claim 1, wherein the first bypass capacitor has the first electrostatic capacity equal to or higher than 5 nanofarads.

4. The power amplifier circuit according to claim 3, wherein the first bypass capacitor has the first electrostatic capacity equal to or lower than 20 nanofarads.

5. The power amplifier circuit according to claim 4, wherein the first bypass capacitor has the first electrostatic capacity equal to or lower than 10 nanofarads.

6. The power amplifier circuit according to claim 1, further comprising:
a first switch coupled between the supply voltage path and the first bypass capacitor; and
a second bypass capacitor coupled between the ground and the supply voltage path, the second bypass capacitor having a second electrostatic capacity that is lower than the first electrostatic capacity of the first bypass capacitor.

7. The power amplifier circuit according to claim 6, wherein:
a second supply voltage is configured in an analog envelope tracking mode that tracks the radio-frequency signal and varies continuously in a voltage level of the second supply voltage;
a second switch is configured to select one of the first supply voltage and the second supply voltage to provide to the supply voltage terminal; and
the first switch is configured to:
when the first supply voltage is supplied to the power amplifier, couple the first bypass capacitor to the supply voltage path; and
when the second supply voltage is supplied to the power amplifier, not couple the first bypass capacitor to the supply voltage path.

8. The power amplifier circuit according to claim 6, wherein:
a second supply voltage is configured in an analog envelope tracking mode that tracks the radio-frequency signal and varies continuously in a voltage level of the second supply voltage;
a second switch configured to select one of the first supply voltage and the second supply voltage to provide to the supply voltage terminal; and
the first switch is configured to:
when the first supply voltage is supplied to the power amplifier and a channel bandwidth of the radio-frequency signal is equal to or greater than a predetermined bandwidth, couple the first bypass capacitor to the supply voltage path; and
when the second supply voltage is supplied to the power amplifier, or when the first supply voltage is supplied to the power amplifier and the channel bandwidth of the radio-frequency signal is smaller than the predetermined bandwidth, not couple the first bypass capacitor to the supply voltage path.

9. The power amplifier circuit according to claim 6, further comprising:
a third bypass capacitor coupled between the ground and the first switch, the third bypass capacitor having a third electrostatic capacity that is different from the first electrostatic capacity of the first bypass capacitor, wherein:
the first switch is configured to:
when a channel bandwidth of the radio-frequency signal is equal to or greater than a predetermined bandwidth, couple the first bypass capacitor to the supply voltage path; and
when the channel bandwidth of the radio-frequency signal is smaller than the predetermined bandwidth, couple the third bypass capacitor to the supply voltage path.

10. The power amplifier circuit according to claim 9, wherein the third electrostatic capacity of the third bypass capacitor is smaller than the first electrostatic capacity of the first bypass capacitor and is greater than the second electrostatic capacity of the second bypass capacitor.

11. A power amplifier circuit comprising:
a power amplifier configured to amplify a radio-frequency signal;
a supply voltage terminal coupled to a digital envelope tracker; and
a first bypass capacitor coupled between a ground and a supply voltage path connecting the supply voltage terminal to the power amplifier,
wherein the first bypass capacitor has a first electrostatic capacity equal to or higher than a value that is determined to cause the power amplifier circuit with the digital envelope tracker to have a higher efficiency than a threshold efficiency.

12. The power amplifier circuit according to claim 11, wherein the threshold efficiency corresponds to an efficiency of the power amplifier circuit in an average power tracking mode.

13. The power amplifier circuit according to claim 11, wherein the first bypass capacitor has the first electrostatic capacity equal to or higher than 5 nanofarads.

14. The power amplifier circuit according to claim 13, wherein the first bypass capacitor has the first electrostatic capacity equal to or lower than 20 nanofarads.

15. The power amplifier circuit according to claim 14, wherein the first bypass capacitor has the first electrostatic capacity equal to or lower than 10 nanofarads.

16. The power amplifier circuit according to claim 11, further comprising:
a first switch coupled between the supply voltage path and the first bypass capacitor; and
a second bypass capacitor coupled between the ground and the supply voltage path, the second bypass capacitor having a second electrostatic capacity lower than the first electrostatic capacity of the first bypass capacitor.

17. The power amplifier circuit according to claim 16, wherein:
a second switch is configured to couple one of the digital envelope tracker and an analog envelope tracker to the supply voltage terminal for providing to the power amplifier, and
the first switch is configured to:
when the digital envelope tracker is coupled to the power amplifier, couple the first bypass capacitor to the supply voltage path; and
when the analog envelope tracker is coupled to the power amplifier, not couple the first bypass capacitor to the supply voltage path.

18. The power amplifier circuit according to claim 16, wherein:
a second switch is configured to couple one of the digital envelope tracker and an analog envelope tracker to the supply voltage terminal for providing to the power amplifier, and
the first switch is configured to:
when the digital envelope tracker is coupled to the power amplifier and a channel bandwidth of the radio-frequency signal is equal to or greater than a predetermined bandwidth, couple the first bypass capacitor to the supply voltage path; and
when the analog envelope tracker is coupled to the power amplifier, or when the digital envelope tracker is coupled to the power amplifier and the channel bandwidth of the radio-frequency signal is smaller than the predetermined bandwidth, not couple the first bypass capacitor to the supply voltage path.

19. The power amplifier circuit according to claim 16, further comprising:
a third bypass capacitor coupled between the ground and the first switch, the third bypass capacitor having a third electrostatic capacity that is different from the first electrostatic capacity of the first bypass capacitor, wherein:
the first switch is configured to:
when a channel bandwidth of the radio-frequency signal is equal to or greater than a predetermined bandwidth, couple the first bypass capacitor to the supply voltage path, and
when the channel bandwidth of the radio-frequency signal is smaller than the predetermined bandwidth, couple the third bypass capacitor to the supply voltage path.

20. The power amplifier circuit according to claim 19, wherein the third electrostatic capacity of the third bypass capacitor is smaller than the first electrostatic capacity of the first bypass capacitor and greater than the second electrostatic capacity of the second bypass capacitor.
